(19) United States
(12) Patent Application Publication
(10) Pub. No.: US 2006/0286487 A1
(43) Pub. Date: Dec. 21, 2006

(54) Process for coating thick resist over polymer features

(76) Inventors: Charles D. Hill, Gilbert, AZ (US); Sriram Muthukumar, Chandler, AZ (US); Patrick A. Dunaway, Chandler, AZ (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/158,168

(22) Filed: Jun. 20, 2005

(51) Int. Cl. G03F 7/26

(52) U.S. Cl. 430/315; 430/311

(57) ABSTRACT

An embodiment of a process is disclosed comprising depositing a sealing layer on a first photoresist layer formed on a substrate, the first photoresist layer having a form patterned and etched therein, depositing a second photoresist layer on the sealing layer, and curing the second photoresist layer by changing its temperature from a first temperature to a second temperature over a set period of time. An embodiment of an apparatus is disclosed comprising a substrate having a first photoresist layer thereon, the first photoresist layer having a form patterned and etched therein, a sealing layer deposited on the first photoresist layer, and a second photoresist layer on the sealing layer, wherein the second photoresist layer is cured by changing its temperature from a first temperature to a second temperature over a set period of time. Other embodiments are disclosed and claimed.

### TECHNICAL FIELD

The present invention relates generally to patterning features on a substrate and in particular, but not exclusively, to applying multiple layers of photoresist to pattern three-dimensional features on a substrate.

### BACKGROUND

Photoresist is commonly used to pattern features on substrates. Much like plywood forms are used in building concrete structures, photoresist layers are usually temporary layers that, when applied and patterned, create forms that can then be filled, coated, etc, with other materials to create structures on a substrate. Once the other materials placed on or in the photoresist are themselves patterned and etched, the photoresist is stripped away, leaving behind a structure on the substrate. Examples of devices in which photoresist is used include microelectronics, microelectromechanical (MEMS) devices, and the like.

In their un-cured form, photoresists are viscous liquids that are applied to the substrate in liquid form and must then be cured before they can be patterned and etched to form features on the substrate. Solvents comprise forty to sixty percent of a typical photoresist, with the remainder being made up of other compounds dissolved in a solvent. Curing involves heating the photoresist so that the solvents evaporate, leaving behind a solid layer.

In some applications it is desirable to use multiple layers of photoresist to create three-dimensional features on a substrate. Certain characteristics of photoresist, however, make this difficult. Cured photoresist is very absorbent of liquids. As a result, if a second layer of photoresist is applied to an existing first layer of cured photoresist, the first layer will absorb solvents from the second layer as soon as the second layer is deposited on the first layer. As it absorbs solvents from the second layer the first layer swells, causing any forms already patterned and etched to deform. The end result is that the first and second layers end up oozing together. In addition to being very absorbent, the viscosity of photoresist can cause gas bubbles to be trapped within the photoresist. As the photoresist is cured, these gas bubbles tend to expand and the photoresist surrounding the gas bubbles hardens, leaving behind voids in the cured second layer. These voids are serious defects that can make it difficult or impossible to properly pattern forms in the cured second layer of photoresist.

### BRIEF DESCRIPTION OF THE DRAWINGS

Non-limiting and non-exhaustive embodiments of the present invention are described with reference to the following figures, wherein like reference numerals refer to like parts throughout the various views unless otherwise specified.

FIG. 1 is a side elevation view of an embodiment of a substrate build-up including a substrate with an etched and patterned first photoresist layer thereon.

FIG. 2 is a side elevation view of an embodiment of the substrate build-up shown in FIG. 1 with a sealing layer deposited thereon.

FIG. 3 is a side elevation view of the embodiment of the substrate build-up shown in FIG. 2 with a second photoresist layer deposited thereon.

FIG. 4A is a side elevation view of the embodiment of the substrate build-up shown in FIG. 3 placed inside an oven for curing.

FIG. 4B is a graph illustrating an embodiment of the variation of temperature over time of the second photoresist layer in the substrate build-up shown in FIG. 4A.

FIG. 4C is a graph illustrating an alternative embodiment of the variation of temperature over time of the second photoresist layer in the substrate build-up shown in FIG. 4A.

FIG. 5A illustrates an embodiment of the substrate build-up shown in FIG. 3 after patterning and etching the second photoresist layer.

FIG. 5B illustrates the embodiment of the substrate build-up shown in FIG. 3 after plating.

FIG. 5C illustrates an embodiment of a free-standing three-dimensional feature remaining on the substrate after the first and second photoresist layers are removed from the embodiment shown in FIG. 5B.

### DETAILED DESCRIPTION OF THE ILLUSTRATED EMBODIMENTS

Embodiments of a process and for applying multiple layers of photoresist on a substrate are described herein. In the following description, numerous specific details are described to provide a thorough understanding of embodiments of the invention. One skilled in the relevant art will recognize, however, that the invention can be practiced without one or more of the specific details, or with other methods, components, materials, etc. In other instances, well-known structures, materials, or operations are not shown or described in detail but are nonetheless encompassed within the scope of the invention.

Reference throughout this specification to “one embodiment” or “an embodiment” means that a particular feature, structure, or characteristic described in connection with the embodiment is included in at least one embodiment of the present invention. Thus, appearances of the phrases “in one embodiment” or “in an embodiment” in this specification do not necessarily all refer to the same embodiment. Furthermore, the particular features, structures, or characteristics may be combined in any suitable manner in one or more embodiments.

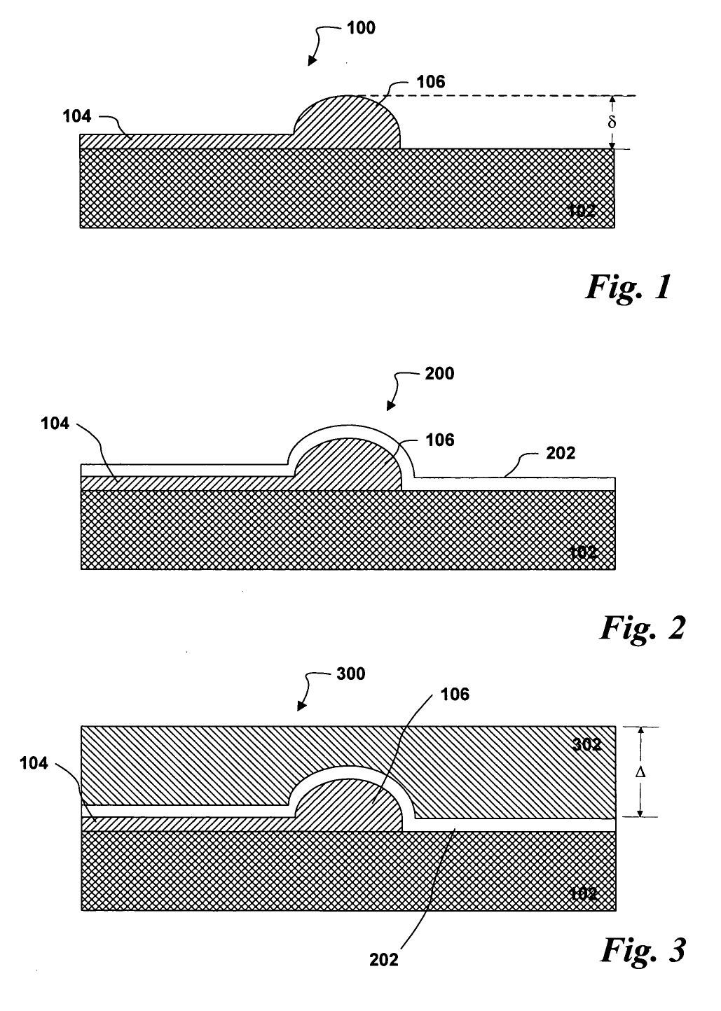

FIG. 1 illustrates an embodiment of a substrate build-up 100 that is a starting point in an embodiment of the process of the present invention. The substrate build-up 100 includes a substrate 102 on which a first photoresist layer 104 has been deposited. The first photoresist layer 104 has been patterned and etched to create a form 106 therein. The substrate 102 can be any substrate on which components can be built. In one embodiment, the substrate 102 can be a silicon substrate, such as those typically used for microelectronic or microelectromechanical (MEMS) devices. In other embodiments, however, other materials such as Gallium Arsenide (GaAs), single crystal silicon (SCS) and so forth can be used as substrates.

The first photoresist layer 104 is deposited on the surface of the substrate 102 and cured. Once cured, the first photoresist layer is patterned and developed (e.g., etched) to created the form 106 therein. In one embodiment, the first photoresist layer is patterned using standard photolithographic techniques in which a mask is used to selectively expose certain areas of the photoresist to radiation. In other embodiments, however, other techniques such as electron beam lithography can be used to pattern the first photoresist layer. Once patterned, the photoresist is developed (e.g., etched) to create the form 106. The form 106 has a height δ and in the embodiment shown it is a rounded form. In other embodiments, the form 106 could be any shape that can be patterned and etched in the first photoresist layer; examples include square, triangular, and other compound and complex shapes.

FIG. 2 illustrates an embodiment of the processing of the substrate build-up shown in FIG. 1. Starting with the initial build-up 100, a sealing layer 202 is deposited over the surface of the substrate 102, as well as over the entire first photoresist layer 106, including over the form 106. One function of the sealing layer 202 is to seal the first photoresist layer 104 from a subsequently-applied second layer of photoresist 302 (see FIG. 3). The sealing layer 202 helps shield the first photoresist layer 104 from solvents that will be escaping from the second photoresist layer 302 during curing. By sealing the first photoresist layer 104 from solvents escaping the second photoresist layer 302, the escaping solvents are not absorbed by the first photoresist layer, and the first photoresist layer therefore remains intact.

The material from which the sealing layer 202 is made depends on the type of feature is being built on the substrate and what subsequent processes will be used to build that feature. In an embodiment where the feature being built is a three-dimensional metal feature formed using a plating process, the sealing layer 202 can be an electrically conductive layer that both seals the first photoresist layer 104 and provides a seed layer for the subsequent plating process. The conductor can be a metal such as copper (Cu), gold (Au), platinum (Pt), silver (Ag) and the like, or can be a conductive non-metal. The method chosen for depositing the sealing layer will depend in part on what material is used. In the embodiment shown, the sealing layer 202 is a metal seed layer deposited by sputtering, which is an example of a physical vapor deposition (PVD) method. In other embodiments the sealing layer can be deposited on the substrate using one or more methods known in the art including, for example, chemical vapor deposition (CVD).

FIG. 3 illustrates an embodiment of the subsequent processing of the substrate build-up 200 shown in FIG. 2. Starting with the substrate build-up 200, a second photoresist layer 302 is applied over the sealing layer 202, such that the sealing layer 202 is sandwiched between the substrate 102 and the second photoresist layer 302, or between the first photoresist layer 104 and the second photoresist layer 302, as the case may be. In one embodiment, the second photoresist layer 302 is made of the same material as the first photoresist layer 104, but in other embodiments the first photoresist layer 104 and second photoresist layer 302 need not be made of the same material.

The second photoresist layer 302 is deposited with thickness Δ; the value of Δ will depend on the height δ of the form 106 in the first photoresist layer, as well as on the desired dimensions of features that will later be formed using the second photoresist layer 302. In one embodiment, δ has a value of 45 μm and the second photoresist layer 302 has a thickness Δ of 70 μm. In another embodiment, δ can have a value of 70 μm and Δ a value of 100 μm. In still other embodiments, δ and Δ each can have values that are different than those in the listed examples and, moreover, δ and Δ need not have the same ratio as those in the listed examples. The second photoresist layer 302 can be deposited on the sealing layer 202 using one or more techniques known in the art, such as spin-coating.

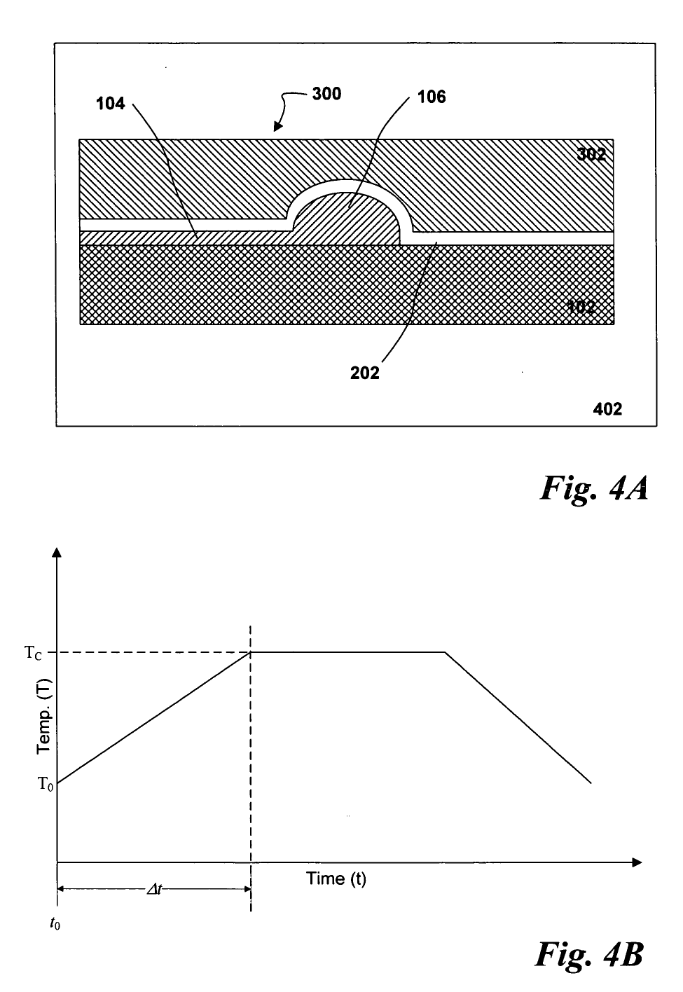

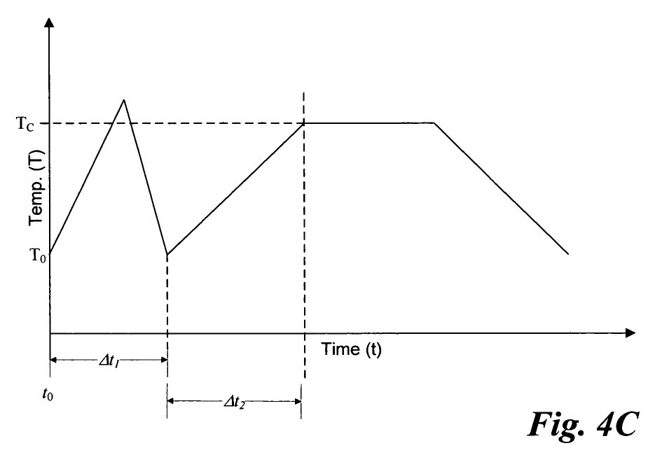

FIGS. 4A-4C illustrate curing of the second photoresist layer 302 of the wafer build-up 300 shown in FIG. 3. After the second photoresist layer 302 is deposited on the sealing layer 202, the entire build-up 300 is placed in an oven or autoclave 402. Once in the oven 402, the build-up 300 is baked so that the second layer of photoresist can be cured.

FIG. 4B illustrates the temperature history of the second photoresist layer 302 while it is cured in the oven 402 as shown in FIG. 4A. The temperature of the second photoresist layer 302 starts out at an initial temperature T₀ at an initial time t₀. In one embodiment, the initial temperature T₀ is the known ambient temperature, but in other embodiments the initial temperature T₀ can be different than ambient. Starting at the temperature T₀, the substrate build-up is ramp-baked, meaning that the temperature inside the oven 402 is increased over time, such that the temperature of the second photoresist layer 302 increases over time as well. In the embodiment shown, the temperature of the second photoresist layer 302 increases from the initial temperature T₀ to the cure temperature T_{C} of the particular photoresist used in the second photoresist layer 302. The cure temperature T_{C} will usually be a value specified by the manufacturer of the photoresist.

The temperature increase from T₀ to T_{C} takes place over a set period of time Δt. The value of Δt can be empirically determined, and will usually depend on the thickness Δ of the second photoresist layer 302, as well as on the particular type of photoresist used. In one embodiment, for example, the initial temperature T₀ is an ambient temperature of about 34° C., the cure temperature T_{C} of the photoresist is about 100° C., and the time Δt is about 650 seconds. In the embodiment shown the increase in temperature of the second photoresist layer 302 between the initial temperature T₀ and the cure temperature T_{C} is linear and monotonic, but in other embodiments the temperature increase need not be linear or monotonic. Ramp-baking the second photoresist layer as shown prevents the formation of voids due to outgassing.

Once the temperature of the second photoresist layer 302 reaches the cure temperature T_{C}, the layer is maintained at that temperature for a period of time necessary for the photoresist to finish curing. Once the photoresist is fully cured, the substrate build-up, and thus the second photoresist layer, is allowed to cool such that it returns roughly to ambient temperature, at which time the second photoresist layer 302 is fully cured and the substrate build-up is ready for subsequent patterning and development (e.g., etching). In other embodiments, however, it may be desirable not to allow the temperature of the second photoresist layer to return to ambient temperature before subsequent processing.

FIG. 4C illustrates an alternative embodiment of a temperature profile that can be used to cure the second photoresist layer 302. In the embodiment shown, the temperature of the second photoresist still increases from the initial temperature T₀ and the cure temperature T_{C} over a period of time Δt, but instead of a monotonic temperature increase there is a preliminary pre-bake in which the temperature ramps up to a temperature greater than the cure temperature T_{C} over a period of time Δt₁ followed by a cooling interval, followed by another heating interval of duration Δt₂ that finally brings the temperature of the second photoresist layer up to the cure temperature T_{C}. In other embodiments, of course, all of these parameters can be varied: other temperature profiles that include more, less of different temperature ramps are possible; the upper and lower temperatures of each temperature ramp can vary; the intervals Δt₁ and Δt₂ can vary; and each temperature ramp need not be linear.

As with the temperature profile shown in FIG. 4B, once the temperature of the second photoresist layer 302 reaches the cure temperature T_{C}, the layer is maintained at that temperature for a period of time necessary for the photoresist to finish curing. Once the photoresist is fully cured, the substrate build-up, and thus the second photoresist layer, is allowed to cool such that it returns roughly to ambient temperature, at which time the second photoresist layer 302 is fully cured and the substrate build-up is ready for subsequent patterning and etching. In other embodiments, however, it may be desirable not to allow the temperature of the second photoresist layer to return to ambient temperature before subsequent processing.

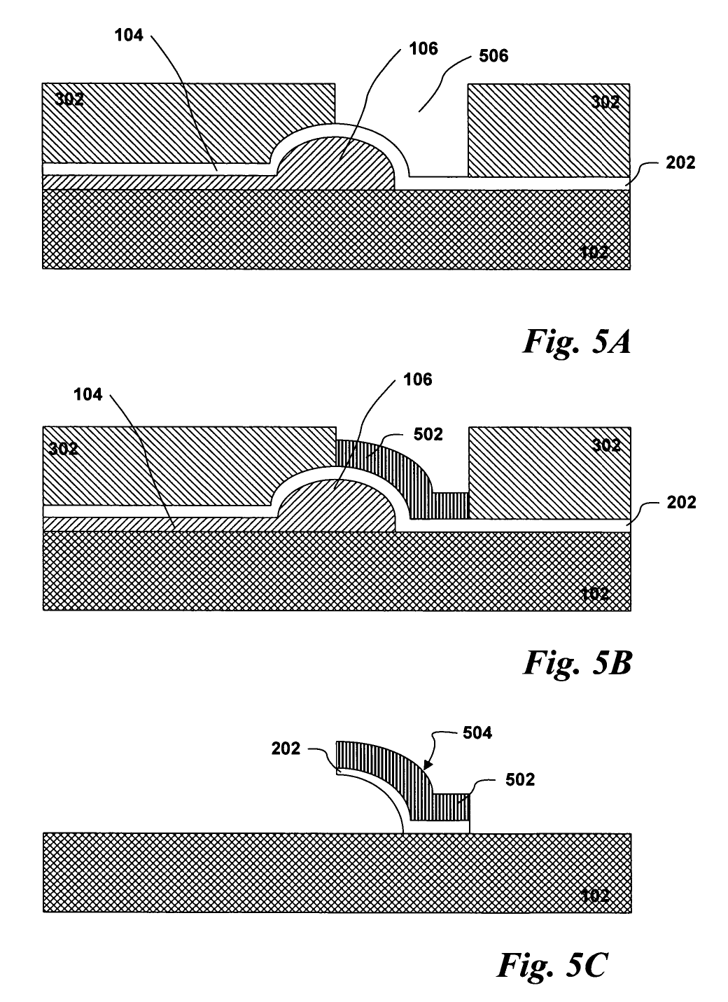

FIGS. 5A-5C illustrate an embodiment of subsequent processing of the substrate build-up after the second photoresist layer is cured as shown in FIGS. 4A-4C. FIG. 5A illustrates the substrate build-up after a trench 506 has been patterned and etched in the second photoresist layer 302. In one embodiment, the second photoresist layer is patterned using standard photolithographic techniques in which a mask is used to selectively expose certain areas of the photoresist to radiation. In other embodiments, however, other techniques such as electron beam lithography can be used to pattern the second photoresist layer. Once patterned, the second photoresist layer 302 is developed (e.g., etched) to create the trench 506.

FIG. 5B illustrates an embodiment the substrate after plating. In this embodiment, the sealing layer 202 is a conductive seed layer made, for example, of copper (Cu). The substrate build-up as shown in FIG. 5A is inserted in a plating bath and an electrical current is applied to the seed layer, causing metal from the plating bath to accumulate with uniform thickness on the sealing layer 202. As metal accumulates, a layer 502 of metal is formed. When the layer 502 reaches the desired thickness, it is fully formed and the plating stops.

FIG. 5C illustrates an embodiment of the feature created by the plating described for FIG. 5B. After plating is complete, the remaining second photoresist layer 302 is stripped away, leaving the feature 502, the sealing layer 202 and the first photoresist layer 104 on the substrate 102. Next, the portions of the sealing layer 202 in the field surrounding the feature 502 are removed. In the embodiment shown, where the sealing layer is copper, the sealing layer is removed with a copper etch. Some of the sealing layer will remain on the lower side of the plating 502, as well as between the plating 502 and the substrate 102. Once the sealing layer 202 is removed from the field, the first photoresist layer 104 is exposed and can be removed from the substrate using standard photoresist stripping techniques.

After the first photoresist layer 104 is removed, a free-standing three-dimensional feature 504 is left behind. The feature 504 includes the plating layer 502 and a portion of the sealing layer 202. Of course, the free-standing feature 504 is merely an example of the type of feature that can be built with the illustrated process embodiment. By constructing the proper free-standing features, or by combining various free-standing features, the process can be used to build devices such as switches, relays, capacitors, inductors, microelectromechanical (MEMS) devices, and the like.

The above description of illustrated embodiments of the invention, including what is described in the abstract, is not intended to be exhaustive or to limit the invention to the precise forms disclosed. While specific embodiments of, and examples for, the invention are described herein for illustrative purposes, various equivalent modifications are possible within the scope of the invention, as those skilled in the relevant art will recognize. These modifications can be made to the invention in light of the above detailed description.

The terms used in the following claims should not be construed to limit the invention to the specific embodiments disclosed in the specification and the claims. Rather, the scope of the invention is to be determined entirely by the following claims, which are to be construed in accordance with established doctrines of claim interpretation.

1. A process comprising:
depositing a sealing layer on a first photoresist layer formed on a substrate, the first photoresist layer having a form patterned and etched therein;
depositing a second photoresist layer on the sealing layer; and
curing the second photoresist layer by changing its temperature from a first temperature to a second temperature over a set period of time.

2. The process of claim 1 wherein the first temperature is a known starting temperature and the second temperature is a curing temperature of the second photoresist layer.

3. The process of claim 2 wherein the first temperature is ambient temperature.

4. The process of claim 1 wherein the set period of time is empirically determined.

5. The process of claim 1 where the temperature change of the second photoresist layer from the first temperature to the second temperature is monotonic over the set period of time.

6. The process of claim 1, further comprising patterning and etching the second photoresist layer.

7. The process of claim 1 wherein the sealing layer is a conductive seed layer.

8. The process of claim 7 wherein the conductive seed layer is copper (Cu), gold (Au), platinum (Pt), silver (Ag), or combinations or alloys thereof.

9. An apparatus comprising:
a substrate having a first photoresist layer thereon, the first photoresist layer having a form patterned and etched therein;
a sealing layer deposited on the first photoresist layer;
and
a second photoresist layer on the sealing layer, wherein the second photoresist layer is cured by changing its temperature from a first temperature to a second temperature over a set period of time.

10. The apparatus of claim 9 wherein the first temperature is a known starting temperature and the second temperature is a curing temperature of the second photoresist layer.

11. The apparatus of claim 9 wherein the set period of time is empirically determined.

12. The apparatus of claim 11 further comprising a feature in the patterned and etched second photoresist layer.

13. The apparatus of claim 9 wherein the sealing layer is a conductive seed layer.

14. The apparatus of claim 13 wherein the conductive seed layer is copper (Cu), gold (Au), platinum (Pt), silver (Ag), or combinations or alloys thereof.

15. An apparatus made by a process comprising:
depositing a sealing layer on a first photoresist layer on a substrate, the first photoresist layer having a form patterned and etched therein;
depositing a second photoresist layer on the sealing layer;
curing the second photoresist layer by changing its temperature from a first temperature to a second temperature over a set period of time;
patterning and etching the second photoresist layer; and
forming one or more features of the apparatus in the patterned and etched second photoresist layer.

16. The apparatus of claim 15 wherein the first temperature is a known starting temperature and the second temperature is a curing temperature of the second photoresist layer.

17. The apparatus of claim 15 wherein the first temperature is ambient temperature.

18. The apparatus of claim 15 wherein the set period of time is empirically determined.

19. The apparatus of claim 15 where the temperature change of the second photoresist layer from the first temperature to the second temperature is monotonic over the set period of time.

20. The apparatus of claim 15 wherein the sealing layer is a conductive seed layer including copper (Cu), gold (Au), platinum (Pt), silver (Ag), or combinations or alloys thereof.
